(19) United States
(12) Patent Application Publication
(10) Pub. No.: US 2015/0069613 A1
(43) Pub. Date: Mar. 12, 2015

(54) SEMICONDUCTOR DEVICE AND MANUFACTURING METHOD THEREOF

(71) Applicant: KABUSHIKI KAISHA TOSHIBA, Tokyo (JP)

(72) Inventors: Tatsuya SHIRAISHI, Ishikawa (JP); Ryota YOSHIOKA, Ishikawa (US)

(73) Assignee: KABUSHIKI KAISHA TOSHIBA, Tokyo (JP)

(21) Appl. No.: 14/194,351

(22) Filed: Feb. 28, 2014

(30) Foreign Application Priority Data
Sep. 12, 2013 (JP) 2013-189422

(51) Int. Cl. H01L 29/45; H01L 21/288

(52) U.S. Cl. CPC H01L 29/456; H01L 21/288
USPC 257/766; 438/652

(57) ABSTRACT

According to one exemplary embodiment, a semiconductor device includes a chip main body; a first layer that is provided on the chip main body and contains nickel and phosphorus; and a second layer that is provided on the first layer and contains nickel and phosphorus and has a higher phosphorus concentration than that of the first layer.

### CROSS-REFERENCE TO RELATED APPLICATION

This application is based upon and claims the benefit of priority from Japanese Patent Application No. 2013-189422, filed Sep. 12, 2013, the entire contents of which are incorporated herein by reference.

### FIELD

Exemplary embodiments described herein generally relate to a semiconductor device and a manufacturing method thereof.

### BACKGROUND

In a power semiconductor device such as an insulated gate bipolar transistor (IGBT), a nickel layer may be provided on a top surface of a chip so as to increase a current density and to provide a relatively high coefficient of heat transfer as compared to silicon in the active portion of the device, to help cool the device. In addition, in such a power semiconductor device, the saturation voltage of the device can be reduced by decreasing the thickness of a chip. However, when the thickness of a chip is decreased, the chip is likely to warp. When a chip is warped, stress applied by the chip to the nickel layer is increased, and cracking may occur in the nickel layer.

### DESCRIPTION OF THE DRAWINGS

FIG. 1(a) is a partial sectional view illustrating a portion of a semiconductor device according to a first exemplary embodiment, and FIG. 1(b) is a graph illustrating a phosphorus concentration distribution in a nickel plated layer of the device in which the vertical axis represents a depth position in the nickel layer and the horizontal axis represents a phosphorus concentration of the nickel layer.

FIG. 2 is a cross-sectional view illustrating of a semiconductor device according to a second exemplary embodiment.

FIG. 3 is a flowchart illustrating the steps of a method of manufacturing a power semiconductor device according to the second exemplary embodiment.

### DETAILED DESCRIPTION

Exemplary embodiments are described for providing a semiconductor device capable of suppressing cracking of part or all of the device, and a manufacturing method thereof.

In general, according to an exemplary embodiment, there is provided a semiconductor device including: a chip main body; a first layer that is provided on the chip main body and which contains nickel and phosphorus; and a second layer that is provided on the first layer, which also contains nickel and phosphorus, and has a higher phosphorus concentration than that of the first layer.

According to another exemplary embodiment, there is provided a method of manufacturing a semiconductor device including: forming a first layer, which contains nickel and phosphorus, on a chip main body using an electroless plating method; and forming a second layer, which contains nickel and phosphorus and has a higher phosphorus concentration than that of the first layer, on the first layer using an electroless plating method.

Hereinafter, exemplary embodiments will be described with reference to the drawings.

First, a first exemplary embodiment will be described.

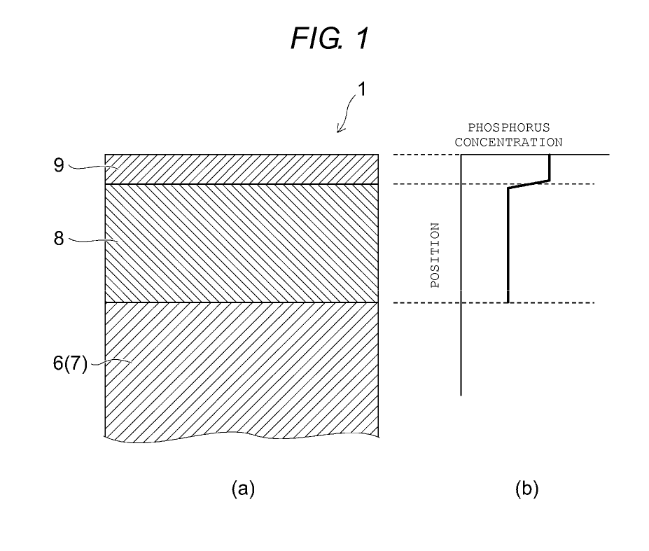

FIG. 1(a) is a partial sectional view illustrating a semiconductor device according to this exemplary embodiment, and FIG. 1(b) is a graph illustrating the phosphorus concentration distribution in a nickel plated layer in which the vertical axis represents a depth position in the plated layer and the horizontal axis represents a phosphorus concentration of the plated layer.

The position represented by the vertical axis of FIG. 1(b) corresponds to the position in the device shown in FIG. 1(a).

As illustrated in FIG. 1 (a), a chip main body 6 is provided in a semiconductor device 1 according to this exemplary embodiment. The chip main body 6 includes a semiconductor portion of the semiconductor device 1; and metal layers that are formed above and below the semiconductor portion. For example, the chip main body 6 includes a silicon portion of an IGBT; and electrode layers that are formed above and below the silicon portion. The uppermost layer of the chip main body 6 is an aluminum layer 7.

A low-dopant concentration plated layer 8 (first layer) is provided on the chip main body 6, and a high-dopant concentration plated layer 9 (second layer) is provided on the low-dopant concentration plated layer 8. The low-dopant concentration plated layer 8 and the high-dopant concentration plated layer 9 are formed using an electroless plating method, are plated nickel layers containing nickel (Ni) as a major component, and contain phosphorus (P) as a dopant therein in addition to the nickel. The low-dopant concentration plating layer 8 and the high-dopant concentration plating layer 9 are in contact with each other. For example, a gold layer (not illustrated) is provided on the high-dopant concentration plated layer 9 as an oxidation prevention layer to protect the underlying nickel from oxidation or corrosion. The low-dopant concentration plated layer 8 and the high-dopant concentration plated layer 9 are a part of a top electrode pad of the semiconductor device 1, for example, a solder joint portion where solder is attached during the packaging of the semiconductor device 1 with a lead frame or the like.

As illustrated in FIG. 1(b), a phosphorus concentration in the high-dopant concentration plated layer 9 is higher than that of the low-dopant concentration plated layer 8. For example, the phosphorus concentration in the low-dopant concentration plated layer 8 is higher than or equal to 4% by mass and lower than 6% by mass, and the phosphorus concentration in the high-dopant concentration plated layer 9 is higher than or equal to 6% by mass and lower than or equal to 7% by mass. In addition, the high-dopant concentration plated layer 9 is thinner than the low-dopant concentration plated layer 8. For example, the thickness of the low-dopant concentration plated layer 8 is approximately 4 μm (micron), and the thickness of the high-dopant concentration plated layer 9 is less than or equal to 1 μm.

Next, a method of manufacturing a semiconductor device according to this exemplary embodiment will be described.

First, as illustrated in FIG. 1(a), the chip main body 6 is prepared. The uppermost layer of the chip main body 6 is the aluminum layer 7.

Next, nickel is plated on the chip main body 6 using an electroless plating method. For example, the plating solution is nickel sulfate (NiSo₄), and the plating solution contains a phosphorus compound such as sodium phosphite (NaH₂PO₂) as a reducing agent. When such a plating solution is used for plating, the reducing agent such as sodium phosphite is oxidized on the aluminum layer 7 as a major reaction, and electrons therein are freed. Nickel ions in the plating solution such as nickel sulfate accept these electrons, and nickel is precipitated from the plating solution to plate on the aluminum layer 7. In addition, as a side reaction, phosphorus in the reducing agent is precipitated and is incorporated into the nickel plated film. In this way, the low-dopant concentration plated layer 8 containing nickel and phosphorus is formed.

Next, the high-dopant concentration plated layer 9 is formed on the low-dopant concentration plated layer 8 using an electroless plating method. At this time, by controlling plating conditions, the phosphorus concentration in the high-dopant concentration plated layer 9 is controlled to be higher than that of the low-dopant concentration plated layer 8. For example, the temperature of the plating solution, the pH of the plating solution, and the kinds and concentrations of additives in the plating solution are controlled as the plating conditions. For example, the higher the pH of the nickel plating solution, the lower the phosphorus concentration in the plated layer. Accordingly, a method may be used, the method including preparing two plating baths having different pH values in advance; forming the low-dopant concentration plated layer 8 using a plating bath having a relatively high pH value; and forming the high-dopant concentration plated layer 9 using a plating bath having a relatively low pH value with a rinse bath interposed between the two baths.

Next, for example, a gold layer (not illustrated) is formed on the high-concentration plating layer 9 as an oxidation preventing layer. As a result, the semiconductor device 1 according to this exemplary embodiment is manufactured.

In this exemplary embodiment, since both the low-dopant concentration plated layer 8 and the high-dopant concentration plated layer 9 are films having a dense structure which are formed using a wet plating method, the number of voids in the films is small. Additionally, the number of phosphorus atoms per unit volume of the high-dopant concentration plated layer 9 is more than the number of phosphorus atoms per unit volume of the low-dopant concentration plated layer 8.

Next, the effects of this exemplary embodiment will be described.

In the semiconductor device 1 according to this exemplary embodiment, the phosphorus concentration in the low-dopant concentration plated layer 8 is lower than that of the high-dopant concentration plated layer 9. During annealing of the layer, or the device, phosphorous compounds can precipitate out of the nickel-phosphorous layer, leading to embrittlement of the nickel-phosphorous layer. The greater the phosphorous concentration in the nickel-phosphorous layer, the more likely precipitated phosphorous compounds can occur, which reduce the ductility (increase the embrittlement) of the layer. Since the phosphorus concentration in the low-dopant concentration plated layer 8 is low, hardening and resulting embrittlement of the film by precipitation of an alloy (for example, Ni₃P) of nickel and phosphorus therein is less likely to occur even after a heat treatment, and the nickel phosphorous first layer remains ductile and able to compensate for stresses induced thereon without cracking. Therefore, the incidence of embrittlement of the plated film by hardening thereof is reduced, and thus cracking of the nickel layer is unlikely to occur. By forming the low-dopant concentration plated layer 8 to be thicker than the high-dopant concentration plated layer 9, the cracking of the semiconductor device 1 can be more effectively suppressed.

In addition, for example, a gold layer is commonly formed on the nickel plated film as an oxidation preventing layer. When the gold layer is formed, the nickel plating film may be already corroded or oxidized. To reduce the likelihood of corrosion/oxidation of a nickel film, the phosphorous is added thereto, and a higher phosphorous concentration yields a film less susceptible to corrosion, but more likely to crack under stress. When the plated film becomes corroded, nickel is eluted from the nickel phosphorous layer-thin gold layer stack at the surface of the gold layer, which causes, for example, formation of a nickel oxide layer thereon and deterioration in solder wettability therewith. The low-dopant concentration plated layer 8 is more easily corroded due to its relatively low phosphorus concentration. Therefore, by forming the high-dopant concentration plated layer 9 on the low-dopant concentration plated layer 8, the corrosion of nickel can be suppressed, and solder wettability can be maintained to be superior during soldering of the device in conjunction with the packaging thereof, while resistance to cracking is increased by the higher ductility first layer.

In this way, according to this exemplary embodiment, the low-dopant concentration plated layer 8 and the high-dopant concentration plated layer 9 are formed one over the other. As a result, cracking of the semiconductor device 1 is suppressed by the soft low-dopant concentration plating layer 8 having a low phosphorus concentration, and solder wettability is secured by the hard high-dopant concentration plating layer 9 having a high phosphorus concentration. Thus, a semiconductor device 1 capable of suppressing cracking and having superior solder wettability can be realized.

On the other hand, if the high-dopant concentration plated layer 9 is not provided, solder wettability is low, and soldering is difficult to perform. Likewise, if the high-dopant concentration plated layer 9 is provided on the lower layer of the two layers and the low-dopant concentration plated layer 8 is provided as an upper layer, solder wettability is insufficient, although resistance to cracking may be improved.

Moreover, after forming the low-dopant concentration plated layer, a high-dopant concentration layer having a relatively high phosphorus concentration may be formed therein by selectively removing nickel by etching from a surface portion of the low-dopant concentration plating layer. As a result, a nickel layer having a higher phosphorus concentration (in a unit volume) in an upper layer than that in a lower layer can be formed. At this time, the number of phosphorus atoms per unit volume of the high-concentration etching layer is equal to the number of phosphorus atoms per unit volume of the low-concentration plating layer. However, in this case, since the high-concentration layer is porous due to etching, the concentration of phosphorous in the upper layer is greater because nickel was removed in that region, but cracking occurs due to embrittlement of the film. Thus, even if the phosphorus concentration is increased by removing nickel without increasing the number of phosphorus atoms per unit volume, cracking is still more likely to occur.

Next, a secondary exemplary embodiment will be described.

This exemplary embodiment is an example in which the configuration of the first exemplary embodiment is applied to an IGBT.

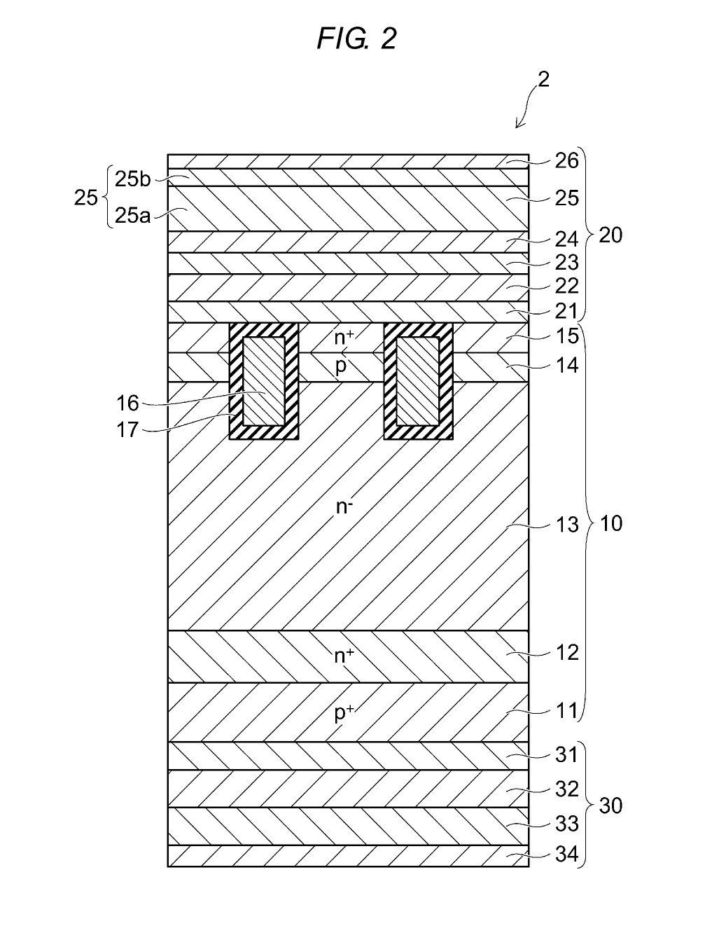

FIG. 2 is a cross-sectional view illustrating a semiconductor device according to this exemplary embodiment.

As illustrated in FIG. 2, a semiconductor device 2 according to this exemplary embodiment is an IGBT. The external shape of the semiconductor device 2 is a chip shape having a length of one side of, for example, 10 mm (millimeter) to 15 mm.

In the semiconductor device 2, a silicon portion 10 is provided as a semiconductor portion, a front electrode structure 20 is provided above the silicon portion 10, and a back electrode structure 30 is provided below the silicon portion 10.

In the silicon portion 10, in order from below, a p⁺ type collector layer 11, an n⁺ type buffer layer 12, an n⁻ type bulk layer 13, a p type base layer 14, and an n⁺ type emitter layer 15 are provided. In addition, a trench gate electrode 16 is provided so as to pass through the n⁺ type emitter layer 15 and the p type base layer 14 from a top surface of the silicon portion 10 and reach the inside of, and terminate within, the n⁻ type bulk layer 13. The trench gate electrode 16 is a base electrode of the semiconductor device 2. A gate insulating film 17 formed of, for example, silicone oxide is provided around the trench gate electrode 16. The silicon portion 10 is formed of single crystalline silicon, and the thickness of the entire silicon portion 10 is, for example, 60 μm to 120 μm, for example, 70 μm.

In the front electrode structure 20, in order from below, that is, in order from the silicon portion 10, a titanium layer 21 having a thickness of, for example, 30 nm (nanometer), a titanium nitride (TiN) layer 22 having a thickness of, for example, 150 nm, an aluminum (Al) layer 23, an aluminum-copper (AlCu) alloy layer 24, a nickel layer 25 having a thickness of, for example, 5 μm, and a gold (Au) layer 26 having a thickness of, for example, 50 nm are laminated. The total thickness of the aluminum layer 23 and the aluminum-copper alloy layer 24 is, for example, 4 μm. The front electrode structure 20 is configured to be an emitter electrode of the semiconductor device 2. The nickel layer 25 and the gold layer 26 are electrode pads which are soldered during packaging using the semiconductor device 2. In addition, the front electrode structure 20 is provided with an interlayer dielectric film (not illustrated).

In the nickel layer 25, a low-dopant concentration plating layer 25a having a relatively low phosphorus concentration and a high-dopant concentration plating layer 25b having a relatively high phosphorus concentration are provided. A configuration of the low-dopant concentration plating layer 25a is the same as that of the low-dopant concentration plating layer 8 of the first exemplary embodiment, and a configuration of the high-dopant concentration plating layer 25b is the same as that of the high-dopant concentration plating layer 9 of the first exemplary embodiment.

In the back electrode structure 30, in order from above, that is, in order from the silicon portion 10, an aluminum-silicon (AlSi) alloy layer 31 having a thickness of, for example, 200 nm, a titanium layer 32 having a thickness of, for example, 200 nm, a nickel layer 33 having a thickness of, for example, 1000 nm, and a gold-silver (AuAg) alloy layer 34 having a thickness of, for example, 100 nm are laminated. The nickel layer 33 is formed using a sputtering method and is formed of substantially pure nickel, and, for example, at least a part or the entire portion thereof is crystallized. The back electrode structure 30 is a collector electrode of the semiconductor device 2.

Next, a method of manufacturing a power semiconductor device according to this exemplary embodiment will be described.

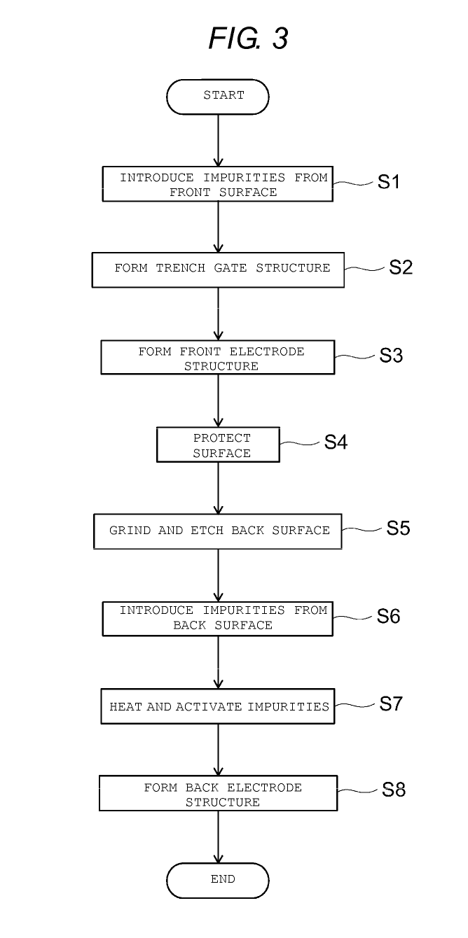

FIG. 3 is a flowchart illustrating the method of manufacturing a power semiconductor device according to this exemplary embodiment.

Hereinafter, the description will be made with reference to FIGS. 2 and 3.

First, an n type silicon wafer is provided as the silicon portion 10. Hereinafter, for convenience of description, this silicon wafer will be referred to as “silicon portion 10”.

As illustrated in Step S1, impurities are introduced from the front surface using an ion implantation method. As a result, the p type base layer 14 and the n⁺ type emitter layer 15 are formed inside the silicon portion 10.

Next, as illustrated in Step S2, a trench is formed, the gate insulating film 17 is formed on the inside of the trench, and the trench gate electrode 16 is embedded into the trench. As a result, a trench gate structure is formed.

Next, as illustrated in Step S3, the front electrode structure 20 is formed on the silicon portion 10. Specifically, using a sputtering method, the titanium layer 21 having a thickness of, for example, 30 nm is formed, the titanium nitride layer 22 having a thickness of, for example, 150 nm is formed, and the aluminum layer 23 and the aluminum-copper alloy layer 24 having a total thickness of, for example, 4 μm is formed. As a result, a chip main body of the semiconductor device 2 is prepared.

Next, nickel is plated using an electroless plating method. At this time, for example, nickel sulfate is used as a plating solution, and sodium phosphite is used as a reducing agent. First, the low-dopant concentration plated layer 25a is formed. The thickness of the low-dopant concentration plated layer 25a is controlled to, for example, 4 μm, and the phosphorus concentration of the low-dopant concentration plated layer 25a is controlled to be higher than or equal to 4% by mass and lower than 6% by mass. Next, the high-dopant concentration plated layer 25b is formed. The thickness of the high-dopant concentration plated layer 25b is controlled to, for example, 1 μm, and the phosphorus concentration of the high-dopant concentration plated layer 25b is controlled to be higher than or equal to 6% by mass and lower than or equal to 7% by mass. As a result, the nickel layer 25 having a thickness of, for example, 5 μm is formed. At this time, the nickel layer 25 is substantially amorphous. Next, the gold layer 26 having a thickness of, for example, 50 nm is formed.

Next, as illustrated in Step S4, a protective tape (not illustrated) is attached onto a top surface of the front electrode structure 20 to protect the surface.

Next, as illustrated in Step S5, a back surface of the silicon portion 10 is ground to decrease the thickness thereof to a predetermined value. Next, a portion of the silicon portion damaged by grinding is removed by wet etching. At this time, the thickness of the silicon portion 10 is, for example, 60 μm to 120 μm and is assumed as, for example, 70 μm. Next, the protective tape is peeled off.

Next, as illustrated in Step S6, impurities are introduced from the back surface of the silicon portion 10 using an ion implantation method. As a result, the n⁺ type buffer layer 12 and the p⁺ type collector layer 11 are formed inside the silicon portion 10.

Next, as illustrated in Step S7, impurities implanted into the silicon portion 10 are activated by a heat treatment. Due to this heat treatment, for example, at least a part or the entire portion of the nickel layer 25 is crystallized.

Next, as illustrated in Step S8, the back electrode structure 30 is formed below the silicon portion 10. Specifically, using a sputtering method, the aluminum-silicon alloy layer 31 having a thickness of, for example, 200 nm is formed, the titanium layer 32 having a thickness of, for example, 200 nm is formed, the nickel layer 33 having a thickness of, for example, 1000 nm is formed, and the gold-silver alloy layer 34 having a thickness of, for example, 100 nm is formed. At this time, since the nickel layer 33 is formed using a sputtering method, at least a part or the entire portion of the nickel layer 33 is crystallized immediately after the film formation.

Next, the silicon wafer (silicon portion 10) is divided into plural chips by being diced along with the front electrode structure 20 and the back electrode structure 30. As a result, the semiconductor device 2 according to this exemplary embodiment is manufactured.

In the semiconductor device 2 according to this exemplary embodiment, cracking is suppressed and solder wettability is superior for the same reason as that of the first exemplary embodiment.

In this exemplary embodiment, the example in which the semiconductor device is an IGBT is described, but the semiconductor device is not limited thereto. For example, a power semiconductor device other than IGBT, for example, a fast recovery diode (FRD) may be formed, and a semiconductor device other than a power semiconductor device may be formed.

According to the above-described exemplary embodiments, a semiconductor device capable of suppressing cracking thereof, and a manufacturing method thereof can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a chip main body;
a first layer that is provided on the chip main body and contains nickel and phosphorus; and
a second layer that is provided on the first layer and contains nickel and phosphorus, the second layer having a higher phosphorus concentration than the phosphorous concentration of the first layer.

2. The semiconductor device according to claim 1,
wherein the phosphorus concentration in the first layer is greater than or equal to 4% by mass and lower than 6% by mass; and
the phosphorus concentration in the second layer is greater than the phosphorus concentration in the first layer.

3. The semiconductor device according to claim 2, wherein phosphorus concentration in the second layer is greater than or equal to 6% by mass and lower than or equal to 7% by mass.

4. The semiconductor device according to claim 1, wherein phosphorus concentration in the second layer is greater than or equal to 6% by mass and lower than or equal to 7% by mass; and
the phosphorus concentration in the first layer is less than the phosphorus concentration in the second layer.

5. The semiconductor device according to claim 1,
wherein the first layer is thicker than the second layer.

6. The semiconductor device according to claim 1,
wherein the number of phosphorus atoms in a unit volume of the second layer is more than the number of phosphorus atoms in the same unit volume of the first layer.

7. The semiconductor device of claim 1, wherein at least one of the first layer and second layer are formed by electroless plating using an electroless plating composition comprising a source of nickel and a source of phosphorous and the phosphorous concentration in the layer is inherently provided by the electroless plating solution.

8. The semiconductor device according to claims 1,
wherein the first layer and the second layer are formed by a plating method.

9. The semiconductor device according to claim 1, wherein the first layer is more ductile than the second layer.

10. The semiconductor device according to claim 1, wherein the second layer is more resistant to oxidation than the first layer.

11. The semiconductor device according to claim 1, further including a gold layer on the second layer.

12. A method of manufacturing a semiconductor device comprising:
forming a first layer, which contains nickel and phosphorus, on a chip main body using an electroless plating method; and
forming a second layer, which contains nickel and phosphorus and has a higher phosphorus concentration than that of the first layer, on the first layer using an electroless plating method.

13. The method of claim 12, wherein the electroless plating solution used to form the first layer is different than the electroless plating solution used to form the second layer.

14. The method of claim 13, wherein the electroless plating solution used to form the first layer has a higher pH value than the pH value of the electroless plating solution used to form the second layer.

15. The method of claim 13, wherein the electroless plating solution comprises nickel sulfate (NiSo₄) and a phosphorus compound.

16. The method of claim 15 wherein the phosphorus compound includes at least sodium phosphite (NaH₂PO₂).

17. An electrode on the outer surface of a power semiconductor device, comprising:
a first layer having a first ductility and a first corrosion resistance;
a second layer having the same components of as the first layer overlying the first layer, and having a second ductility lower than the ductility of the first layer and an oxidation resistance greater than the oxidation resistance of the first layer.

18. The electrode of claim 17, wherein the first layer and second layer comprise nickel and phosphorous, and the phosphorous concentration in the second layer is greater than the phosphorous concentration in the first layer.

19. The electrode of claim 17, wherein the first layer is thicker than the second layer.

20. The electrode of claim 17, further including a gold layer on the second layer, the gold layer thinner than the thickness of the first layer and the thickness of the second layer.
